(19) United States
(12) Patent Application Publication
(10) Pub. No.: US 2026/0150388 A1
(43) Pub. Date: May 28, 2026

(54) DIODE DEVICE

(71) Applicant: KABUSHIKI KAISHA TOSHIBA, Tokyo (JP)

(72) Inventor: Tomoaki INOKUCHI, Yokohama (JP)

(73) Assignee: KABUSHIKI KAISHA TOSHIBA, Tokyo (JP)

(21) Appl. No.: 19/256,432

(22) Filed: Jul. 1, 2025

(30) Foreign Application Priority Data
Nov. 28, 2024 (JP) 2024-207498

(51) Int. Cl. H10D 84/80; H03K 17/687; H03K 17/693; H10D 8/25; H10D 62/10; H10D 62/60; H10D 64/00; H10D 64/23; H10D 64/27; H10D 64/64

(52) U.S. Cl. CPC H10D 84/811; H03K 17/6877; H03K 17/693; H10D 8/25; H10D 62/103; H10D 62/126; H10D 62/60; H10D 64/112; H10D 64/256; H10D 64/513; H10D 64/647

(57) ABSTRACT

According to one embodiment, a diode device includes first and second terminals, a transistor element, a control circuit, and a voltage generating circuit. The transistor element includes source, drain and gate electrodes. The source electrode is connected to the first terminal. The drain electrode is connected to the second terminal. The control circuit includes first and second input portions, a control output portion, and a control power supply input portion. The first and second control input portions are connected to the first and second terminal respectively. The control output portion is connected to the gate electrode. The voltage generating circuit includes first and second voltage input portions, and a voltage output portion. The first voltage input portion is connected to the first terminal. The second voltage input portion is connected to the second terminal. The voltage output portion is connected to the control power supply input portion.

### CROSS-REFERENCE TO RELATED APPLICATIONS

This application is based upon and claims the benefit of priority from Japanese Patent Application No. 2024-207498, filed on Nov. 28, 2024; the entire contents of which are incorporated herein by reference.

### FIELD

Embodiments described herein relate generally to a diode device.

### BACKGROUND

For example, in diode devices, improved characteristics are desired.

### BRIEF DESCRIPTION OF THE DRAWINGS

FIG. 1 is a schematic diagram illustrating a diode device according to a first embodiment;

FIG. 2 is a schematic diagram illustrating the characteristics of the diode device according to the first embodiment;

FIG. 3 is a schematic diagram illustrating a part of the diode device according to the first embodiment;

FIG. 4 is a schematic diagram illustrating a part of the diode device according to the first embodiment;

FIG. 5 is a schematic cross-sectional view illustrating a part of the diode device according to the first embodiment;

FIG. 6 is a schematic perspective view illustrating a part of the diode device according to the first embodiment;

FIG. 7 is a schematic cross-sectional view illustrating a part of the diode device according to the first embodiment;

FIGS. 8A to 8C are schematic diagrams illustrating electric circuits according to a second embodiment; and

FIG. 9 is a schematic diagram illustrating an electric circuit according to the second embodiment.

### DETAILED DESCRIPTION

According to one embodiment, a diode device includes a first terminal, a second terminal, a transistor element, a control circuit, and a voltage generating circuit. The transistor element includes a source electrode, a drain electrode, and a gate electrode. The source electrode is electrically connected to the first terminal. The drain electrode is electrically connected to the second terminal. The control circuit includes a first control input portion, a second control input portion, a control output portion, and a control power supply input portion. The first control input portion is electrically connected to the first terminal. The second control input portion is electrically connected to the second terminal. The control output portion is electrically connected to the gate electrode. The voltage generating circuit includes a first voltage input portion, a second voltage input portion, and a voltage output portion. The first voltage input portion is electrically connected to the first terminal. The second voltage input portion is electrically connected to the second terminal. The voltage output portion is electrically connected to the control power supply input portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

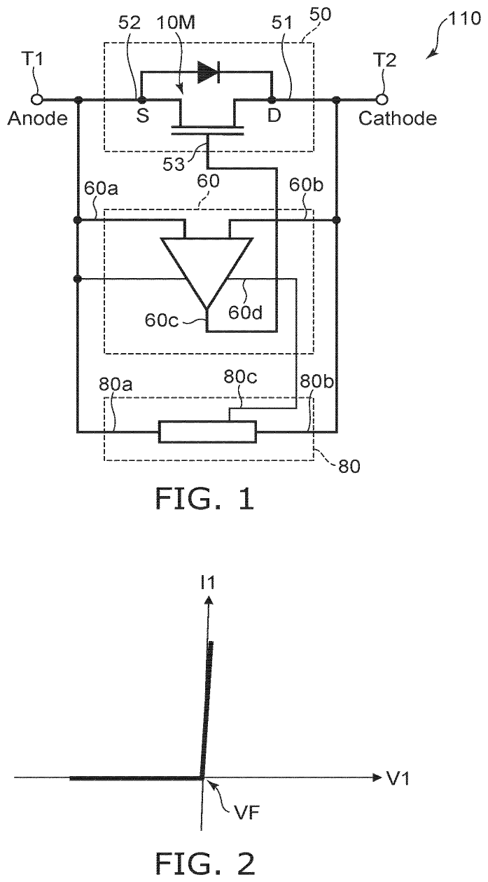

FIG. 1 is a schematic diagram illustrating a diode device according to a first embodiment.

As shown in FIG. 1, a diode device 110 according to an embodiment includes a first terminal T1, a second terminal T2, a transistor element 50, a control circuit 60, and a voltage generating circuit 80.

The transistor element 50 includes a source electrode 52, a drain electrode 51, and a gate electrode 53. The source electrode 52 is electrically connected to the first terminal T1. The drain electrode 51 is electrically connected to the second terminal T2.

The control circuit 60 includes a first control input portion 60a, a second control input portion 60b, a control output portion 60c, and a control power supply input portion 60d. The first control input portion 60a is electrically connected to the first terminal T1. The second control input portion 60b is electrically connected to the second terminal T2. The control output portion 60c is electrically connected to the gate electrode 53.

The voltage generating circuit 80 includes a first voltage input portion 80a, a second voltage input portion 80b, and a voltage output portion 80c. The first voltage input portion 80a is electrically connected to the first terminal T1. The second voltage input portion 80b is electrically connected to the second terminal T2. The voltage output portion 80c is electrically connected to the control power supply input portion 60d.

In the diode device 110, the first terminal T1 is, for example, an anode terminal. The second terminal T2 is, for example, a cathode terminal. The diode device 110 is a two-terminal device. The number of terminals is two. No terminal other than the two terminals need be provided. In the embodiment, the diode device 110 with a simple configuration is obtained.

FIG. 2 is a schematic diagram illustrating the characteristics of the diode device according to the first embodiment.

The horizontal axis of FIG. 2 is the voltage V1 between the first terminal T1 and the second terminal T2. The vertical axis is the current I1 flowing between the first terminal T1 and the second terminal T2. As shown in FIG. 2, in the diode device 110, for example, the forward voltage VF is substantially 0. This makes it possible to suppress losses. According to the embodiment, a diode device with improved characteristics can be obtained with a simple configuration.

The diode device 110 may be applied to, for example, synchronous rectification. Even in such an application, the circuit does not become complicated. Losses in light loads are suppressed.

In the embodiment, when a reverse voltage is applied between the first terminal T1 and the second terminal T2, a constant voltage is generated by the voltage generating circuit 80. As described later, for example, the voltage generating circuit 80 includes a capacitor. When a reverse voltage is applied, the control circuit 60 is driven by the charge stored in the capacitor. The control circuit 60 controls the transistor element 50. For example, when the charge stored in the capacitor is consumed, a rectification operation is performed by the body diode of the transistor element 50.

Thus, the control circuit 60 is configured to control the gate potential of the gate electrode 53 based on the result of comparing the first potential of the first terminal T1 and the second potential of the second terminal T2.

The voltage generating circuit 80 is configured to output a substantially constant voltage based on the voltage between the first terminal T1 and the second terminal T2.

Below, an example of the configuration of the voltage generating circuit 80 will be described.

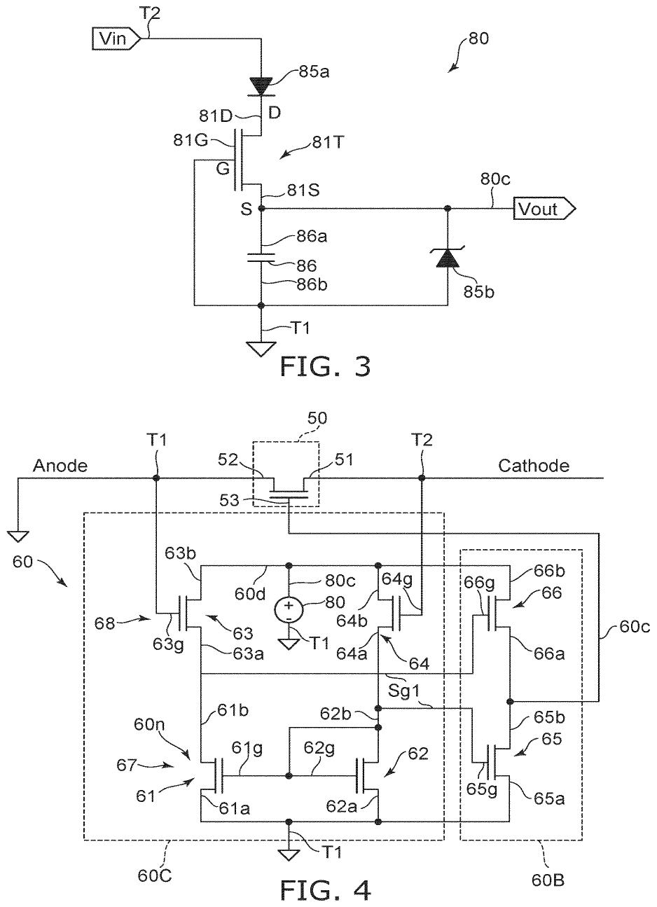

FIG. 3 is a schematic diagram illustrating a part of the diode device according to the first embodiment.

As shown in FIG. 3, in this example, the voltage generating circuit 80 includes a first voltage generating diode 85a, a first voltage generating transistor 81T, and a first capacitor 86.

The anode (first voltage generating anode) of the first voltage generating diode 85a is electrically connected to the second terminal T2. The cathode (first voltage generating cathode) of the first voltage generating diode 85a is electrically connected to the first voltage generating drain 81D of the first voltage generating transistor 81T. The first voltage generating source 81S of the first voltage generating transistor 81T is electrically connected to the first capacitor end 86a of the first capacitor 86 and the voltage output portion 80c.

The first capacitor other end 86b of the first capacitor 86 and the first voltage generating gate 81G of the first voltage generating transistor 81T are electrically connected to the first terminal T1.

For example, the first voltage generating transistor 81T is a depletion mode MOS transistor. The threshold voltage of the first voltage generating transistor 81T is negative. The threshold voltage may be, for example, about −2V. For example, when the potential of the first voltage generating source 81S rises to the threshold voltage, the first voltage generating transistor 81T is turned off. The circuit illustrated in FIG. 3 enables the operation described with reference to FIG. 1.

As shown in FIG. 3, the voltage generating circuit 80 may further include a second voltage generating diode 85b. The anode (second voltage generating anode) of the second voltage generating diode 85b is electrically connected to the first terminal T1. The cathode (second voltage generating cathode) of the second voltage generating diode 85b is electrically connected to the voltage output portion 80c. The second voltage generating diode 85b functions, for example, as a diode for suppressing reverse current. The second voltage generating diode 85b may be a Zener diode.

In the embodiment, the voltage generating circuit 80 may be of any configuration that can output a substantially constant voltage based on the voltage between the first terminal T1 and the second terminal T2.

Below, an example of the configuration of the control circuit 60 will be described.

FIG. 4 is a schematic diagram illustrating a part of the diode device according to the first embodiment.

As shown in FIG. 4, in this example, the control circuit 60 includes a comparison circuit 60C. The comparison circuit 60C is configured to output a signal Sg1 based on the difference between a first potential at the first terminal T1 and a second potential at the second terminal T2.

The comparison circuit 60C may include, for example, a current mirror circuit 67 and a differential circuit pair 68.

In this example, the control circuit 60 further includes a buffer circuit 60B. The buffer circuit 60B is provided between the comparison circuit 60C and the control output portion 60c.

The comparison circuit 60C may include one or more nMOS transistors 60n. The buffer circuit 60B may include one or more nMOS transistors 60n.

In the example shown in FIG. 4, the control circuit 60 includes a first transistor 61, a second transistor 62, a third transistor 63, and a fourth transistor 64.

A first end 61a of the first transistor 61 and a second end 62a of the second transistor 62 are electrically connected to the first terminal T1. A first other end 61b of the first transistor 61 is electrically connected to a third end 63a of the third transistor 63. A second other end 62b of the second transistor 62 is electrically connected to a fourth end 64a of the fourth transistor 64.

The third other end 63b of the third transistor 63 and the fourth other end 64b of the fourth transistor 64 are electrically connected to the control power supply input portion 60d. As already explained, the control power supply input portion 60d is electrically connected to the voltage output portion 80c of the voltage generating circuit 80.

A first gate 61g of the first transistor 61 and a second gate 62g of the second transistor 62 are electrically connected to the second other end 62b of the second transistor 62. A third gate 63g of the third transistor 63 is electrically connected to the first terminal T1. A fourth gate 64g of the fourth transistor 64 is electrically connected to the second terminal T2.

The first transistor 61, the second transistor 62, the third transistor 63, and the fourth transistor 64 form, for example, a comparison circuit 60C.

At least one of the first transistor 61, the second transistor 62, the third transistor 63, or the fourth transistor 64 may be an nMOS transistor 60n.

As shown in FIG. 4, the control circuit 60 may further include a fifth transistor 65 and a sixth transistor 66. A fifth end 65a of the fifth transistor 65 is electrically connected to the first terminal T1. A fifth other end 65b of the fifth transistor 65 is electrically connected to the control output portion 60c. A sixth end 66a of the sixth transistor 66 is electrically connected to the control output portion 60c. A sixth other end 66b of the sixth transistor 66 is electrically connected to the control power supply input portion 60d.

A fifth gate 65g of the fifth transistor 65 is electrically connected to the second other end 62b. A sixth gate 66g of the sixth transistor 66 is electrically connected to the first other end 61b.

The fifth transistor 65 and the sixth transistor 66 form, for example, the buffer circuit 60B. At least one of the fifth transistor 65 or the sixth transistor 66 may be an nMOS transistor 60n.

In the embodiment, the control circuit 60 may be any configuration capable of outputting the signal Sg1 based on the difference between the first potential of the first terminal T1 and the second potential of the second terminal T2.

Below, one example of the configuration of the transistor element 50 will be described.

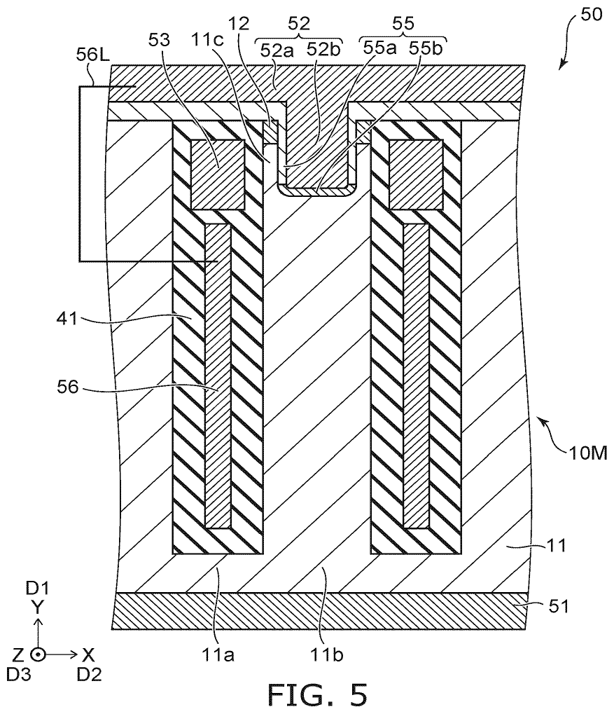

FIG. 5 is a schematic cross-sectional view illustrating a part of the diode device according to the first embodiment.

As shown in FIG. 5, in this example, the transistor element 50 further includes a semiconductor member 10M, a metal member 55, and a first insulating member 41.

The semiconductor member 10M is located between the drain electrode 51 and the source electrode 52 in a first direction D1 from the drain electrode 51 to the source electrode 52.

The first direction D1 is defined as a Y-axis direction. One direction perpendicular to the Y-axis direction is defined as an X-axis direction. A direction perpendicular to the Y-axis and X-axis directions is defined as a Z-axis direction.

The source electrode 52 includes a first electrode portion 52a and a second electrode portion 52b. The second electrode portion 52b is electrically connected to the first electrode portion 52a.

The semiconductor member 10M includes a first semiconductor region 11 of a first conductivity type. The first semiconductor region 11 includes a first partial region 11a, a second partial region 11b, and a third partial region 11c. The gate electrode 53 is located between the drain electrode 51 and the first electrode portion 52a in the first direction D1.

A direction from the second partial region 11b to the second electrode portion 52b is along the first direction D1. The third partial region 11c is located between the gate electrode 53 and the second electrode portion 52b in a second direction D2 crossing the first direction D1. The second direction D2 may be, for example, the X-axis direction.

The metal member 55 includes a first metal portion 55a. The first metal portion 55a is located between the gate electrode 53 and the second electrode portion 52b in the second direction D2. The first metal portion 55a forms a Schottky contact with the first semiconductor region 11 (e.g., the third partial region 11c).

At least a part of the first insulating member 41 is located between the gate electrode 53 and the semiconductor member 10M. The first insulating member 41 electrically insulates between the gate electrode 53 and the semiconductor member 10M.

For example, current flowing between the source electrode 52 and the drain electrode 51 can be controlled by a potential of the gate electrode 53. For example, the state (e.g., thickness) of the Schottky barrier in the third partial region 11c and the first metal portion 55a is controlled by the potential of the gate electrode 53. Thereby, the current is controlled. The transistor element 50 is, for example, a Schottky barrier transistor.

For example, the first metal portion 55a may include at least one selected from the group consisting of Ti, W, Mo, Ta, Zr, Al, Sn, V, Re, Os, Ir, Pt, Pd, Rh, Ru, Nb, Sr, and Hf. A Schottky barrier is obtained stably.

As shown in FIG. 5, the metal member 55 may further include a second metal portion 55b. The second metal portion 55b is located between the first partial region 11a and the second electrode portion 52b in the first direction D1. A direction from at least a part of the gate electrode 53 to the second metal portion 55b is along the second direction D2. The material of the second metal portion 55b may be different from the material of the first metal portion 55a. Thereby, the forward voltage VF of the body diode can be adjusted.

In one example, a second work function of the second metal portion 55b is lower than a first work function of the first metal portion 55a. For example, the forward voltage VF being low can be obtained easily.

As shown in FIG. 5, the semiconductor member 10M may further include a second semiconductor region 12 of the first conductivity type. The second semiconductor region 12 is located between the first semiconductor region 11 and the source electrode 52. A second impurity concentration of the first conductivity type in the second semiconductor region 12 is higher than a first impurity concentration of the first conductivity type in the first semiconductor region 11. A low on-resistance is obtained.

The first conductivity type may be n-type. The first semiconductor region 11 is, for example, an n-region. The second semiconductor region 12 is, for example, an n⁺-region. The semiconductor member 10M may include, for example, silicon or SiC. The semiconductor member 10M may include, for example, a compound semiconductor including Ga.

The transistor element 50 may include a first conductive member 56. The first conductive member 56 is electrically connected to the source electrode 52. For example, at a position different from the cross section of FIG. 5, the first conductive member 56 is electrically connected to the source electrode 52 by a connection member 56L or the like. A position of the first conductive member 56 in the first direction D1 is between a position of the drain electrode 51 in the first direction D1 and a position of the gate electrode 53 in the first direction D1. The first conductive member 56 functions as, for example, a field plate. Local concentration of the electric field is suppressed. A high breakdown voltage is easily obtained.

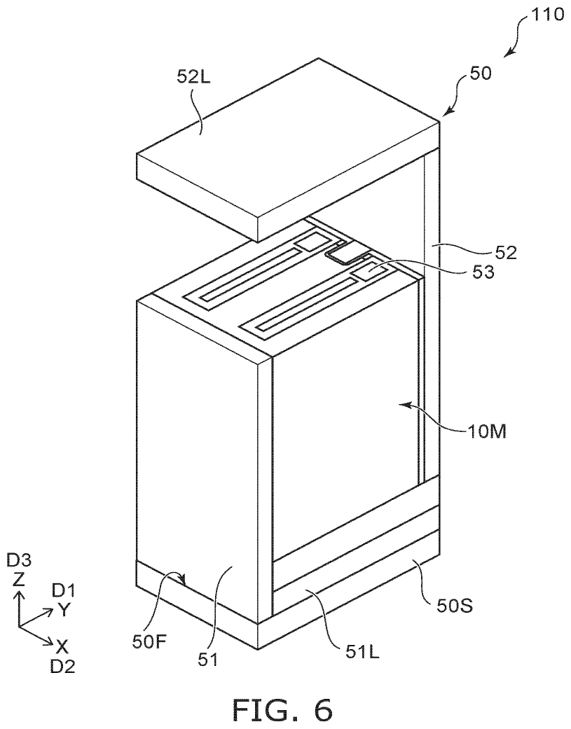

FIG. 6 is a schematic perspective view illustrating a part of the diode device according to the first embodiment.

As shown in FIG. 6, the diode device 110 may include a base 50S. The base 50S includes a base face 50F.

A third direction D3 from the base face 50F to the transistor element 50 crosses the base face 50F. The third direction D3 crosses, for example, a plane including the first direction D1 and the second direction D2. The gate electrode 53 extends along the third direction D3. The base face 50F of the base 50S may be insulating. The region including the base face 50F may include, for example, silicon oxide.

As shown in FIG. 6, the transistor element 50 may include a drain electrode layer 51L electrically connected to the drain electrode 51. The transistor element 50 may include a source electrode layer 52L electrically connected to the source electrode 52. The semiconductor member 10M is located between the drain electrode layer 51L and the source electrode layer 52L. These electrode layers cross the third direction D3. These electrode layers are, for example, along the X-Y plane.

In this example, the drain electrode layer 51L is located between the base 50S and the source electrode layer 52L. In the embodiment, the source electrode layer 52L may be located between the base 50S and the drain electrode layer 51L.

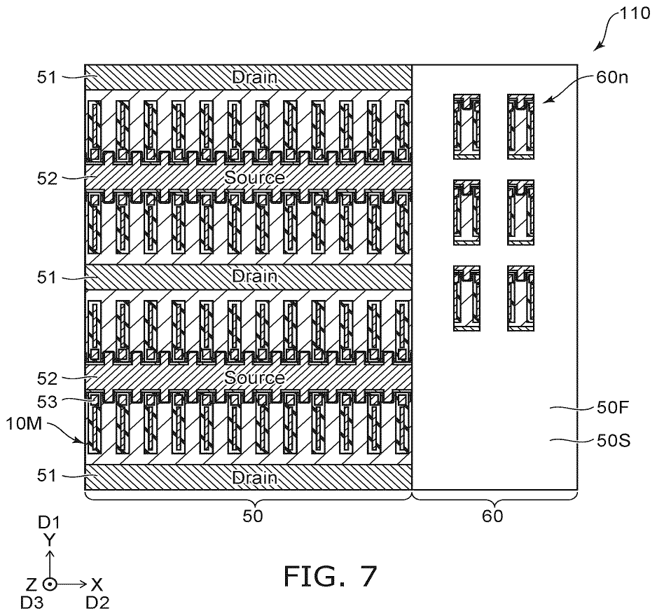

FIG. 7 is a schematic cross-sectional view illustrating a part of the diode device according to the first embodiment.

As shown in FIG. 7, the transistor element 50 and the control circuit 60 may be provided on one base 50S. The direction from the base face 50F to the transistor element 50 is along the third direction D3. The direction from the base face 50F to the control circuit 60 is along the third direction D3. The transistor element 50 and the control circuit 60 can be obtained with a simple configuration.

The transistor element 50 may include a plurality of gate electrodes 53. The plurality of gate electrodes 53 are arranged along the second direction D2. The transistor element 50 may include a stack including the drain electrode 51, the source electrode 52, the plurality of gate electrodes 53, and the semiconductor member 10M. The transistor element 50 may include a plurality of stacks. The plurality of stacks may be arranged along the first direction D1.

### Second Embodiment

The second embodiment relates to an electric circuit. The electric circuit includes the diode device 110 described in relation to the first embodiment or a variation thereof.

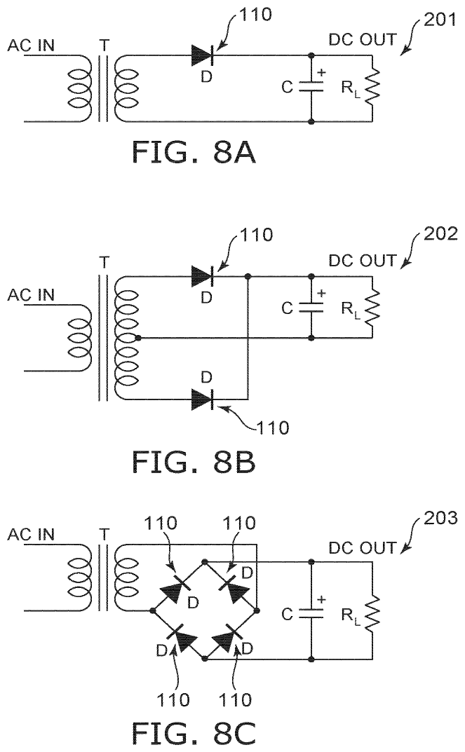

FIGS. 8A to 8C are schematic diagrams illustrating electric circuits according to the second embodiment.

As shown in FIG. 8A, an electric circuit 201 according to the embodiment is a half-wave rectifier circuit. As shown in FIG. 8B, an electric circuit 202 according to the embodiment is a half-wave rectifier circuit. As shown in FIG. 8C, an electric circuit 203 according to the embodiment is a full-wave rectifier circuit. The diode device 110 according to the first embodiment may be applied as the diode included in these electric circuits.

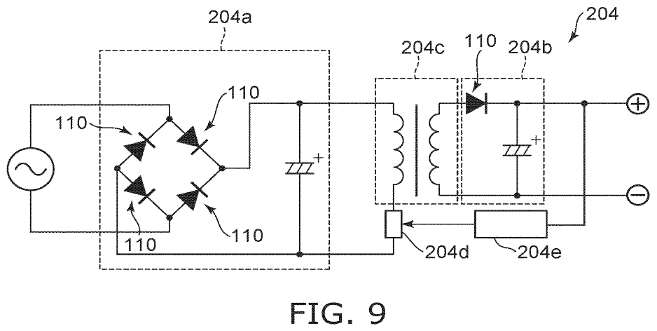

FIG. 9 is a schematic diagram illustrating an electric circuit according to the second embodiment.

As shown in FIG. 9, an electric circuit 204 according to the embodiment includes, for example, a full-wave rectifier circuit 204a and a half-wave rectifier circuit 204b. The diode device 110 according to the first embodiment may be applied to these rectifier circuits. In this example, the electric circuit 204 includes a switching transformer 204c, a switching semiconductor element 204d, and a control electric circuit 204e.

The embodiment may include the following Technical proposals:

### Technical Proposal 1

A diode device, comprising:
a first terminal;
a second terminal;
a transistor element including a source electrode, a drain electrode, and a gate electrode, the source electrode being electrically connected to the first terminal, the drain electrode being electrically connected to the second terminal;
a control circuit including a first control input portion, a second control input portion, a control output portion, and a control power supply input portion, the first control input portion being electrically connected to the first terminal, the second control input portion being electrically connected to the second terminal, the control output portion being electrically connected to the gate electrode;
a voltage generating circuit including a first voltage input portion, a second voltage input portion, and a voltage output portion, the first voltage input portion being electrically connected to the first terminal, the second voltage input portion being electrically connected to the second terminal, the voltage output portion being electrically connected to the control power supply input portion.

### Technical Proposal 2

The diode device according to Technical proposal 1, wherein
the control circuit is configured to control a gate potential of the gate electrode based on a result of comparing a first potential of the first terminal with a second potential of the second terminal.

### Technical Proposal 3

The diode device according to Technical proposal 2, wherein
the control circuit includes a comparison circuit,
the comparison circuit is configured to output a signal based on a difference between the first potential and the second potential.

### Technical Proposal 4

The diode device according to Technical proposal 3, wherein
the comparison circuit includes a current mirror circuit and a differential circuit pair.

### Technical Proposal 5

The diode device according to Technical proposal 4, wherein
the control circuit includes a buffer circuit,
the buffer circuit is provided between the comparison circuit and the control output portion.

### Technical Proposal 6

The diode device according to any one of technical proposals 3-5, wherein
the comparison circuit includes one or more nMOS transistors.

### Technical Proposal 7

The diode device according to Technical proposal 2 or 3, wherein
the control circuit includes a first transistor, a second transistor, a third transistor, and a fourth transistor,
a first end of the first transistor and a second end of the second transistor are electrically connected to the first terminal,
a first other end of the first transistor is electrically connected to a third end of the third transistor,
a second other end of the second transistor is electrically connected to a fourth end of the fourth transistor,
a third other end of the third transistor and the fourth other end of the fourth transistor are electrically connected to the control power supply input portion,
a first gate of the first transistor and a second gate of the second transistor are electrically connected to the second other end,
a third gate of the third transistor is electrically connected to the first terminal, and
a fourth gate of the fourth transistor is electrically connected to the second terminal

### Technical Proposal 8

The diode device according to Technical proposal 7, wherein
at least one of the first transistor, the second transistor, the third transistor, or the fourth transistor is an nMOS transistor.

### Technical Proposal 9

The diode device according to Technical proposal 7, wherein
the control circuit further includes a fifth transistor and a sixth transistor,
a fifth end of the fifth transistor is electrically connected to the first terminal,
a fifth other end of the fifth transistor is electrically connected to the control output portion,
a sixth end of the sixth transistor is electrically connected to the control output portion,
a sixth other end of the sixth transistor is electrically connected to the control power supply input portion,
a fifth gate of the fifth transistor is electrically connected to the second other end, and
a sixth gate of the sixth transistor is electrically connected to the first other end.

### Technical Proposal 10

The diode device according to Technical proposal 9, wherein
at least one of the fifth transistor or the sixth transistor is an nMOS transistor.

### Technical Proposal 11

The diode device according to any one of Technical proposals 1-10, wherein
the voltage generating circuit is configured to output a constant voltage based on a voltage between the first terminal and the second terminal.

### Technical Proposal 12

The diode device according to any one of technical proposals 1-10, wherein
the voltage generating circuit includes a first voltage generating diode, a first voltage generating transistor, and a first capacitor,
a first voltage generating anode of the first voltage generating diode is electrically connected to the second terminal,
a first voltage generating cathode of the first voltage generating diode is electrically connected to a first voltage generating drain of the first voltage generating transistor,
a first voltage generating source of the first voltage generating transistor is electrically connected to a first capacitor end of the first capacitor and the voltage output portion,
a first capacitor other end of the first capacitor and a first voltage generating gate of the first voltage generating transistor are electrically connected to the first terminal, and
the first voltage generating transistor is a depletion mode MOS transistor.

### Technical Proposal 13

The diode device according to Technical proposal 12, wherein
the voltage generating circuit further includes a second voltage generating diode,
a second voltage generating anode of the second voltage generating diode is electrically connected to the first terminal, and
a second voltage generating cathode of the second voltage generating diode is electrically connected to the voltage output portion.

### Technical Proposal 14

The diode device according to Technical proposal 13, wherein
the second voltage generating diode is a Zener diode.

### Technical Proposal 15

The diode device according to any one of Technical proposals 1-14, wherein
the transistor element includes a Schottky barrier transistor.

### Technical Proposal 16

The diode device according to any one of Technical proposals 1-14, wherein
the transistor element further includes a semiconductor member, a metal member, and a first insulating member,
the semiconductor member is located between the drain electrode and the source electrode in a first direction from the drain electrode to the source electrode,
the source electrode includes a first electrode portion and a second electrode portion,
the semiconductor member includes a first semiconductor region of a first conductivity type,
the first semiconductor region includes a first partial region, a second partial region, and a third partial region,
the gate electrode is located between the drain electrode and the first electrode portion in the first direction,
a direction from the second partial region to the second electrode portion is along the first direction,
the third partial region is located between the gate electrode and the second electrode portion in a second direction crossing the first direction,
the metal member includes a first metal portion,
the first metal portion is located between the gate electrode and the second electrode portion in the second direction,
the first metal portion forms a Schottky contact with the third partial region,
at least a part of the first insulating member is located between the gate electrode and the semiconductor member.

### Technical Proposal 17

The diode device according to Technical proposal 16, wherein
the first metal portion includes at least one selected from the group consisting of Ti, W, Mo, Ta, Zr, Al, Sn, V, Re, Os, Ir, Pt, Pd, Rh, Ru, Nb, Sr, and Hf.

### Technical Proposal 18

The diode device according to Technical proposal 16 or 17, wherein
the metal member further includes a second metal portion,
the second metal portion is located between the first partial region and the second electrode portion in the first direction,
a direction from at least a part of the gate electrode to the second metal portion is along the second direction, and
a second work function of the second metal portion is lower than a first work function of the first metal portion.

### Technical Proposal 19

The diode device according to any one of Technical proposals 16-18, wherein
the semiconductor member further includes a second semiconductor region of the first conductivity type,
the second semiconductor region is located between the first semiconductor region and the source electrode,
a second impurity concentration of the first conductivity type in the second semiconductor region is higher than a first impurity concentration of the first conductivity type in the first semiconductor region.

### Technical Proposal 20

The diode device according to any one of technical proposals 1-19, further comprising:
a base including a base face,
a third direction from the base face to the transistor element crossing the base face, and
a direction from the base face to the control circuit being along the third direction.

According to the embodiment, a diode device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor drive devices and the semiconductor modules such as circuit sections, circuits, semiconductor devices, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor drive devices and all semiconductor modules practicable by an appropriate design modification by one skilled in the art based on the semiconductor drive devices and the semiconductor modules described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A diode device, comprising:
a first terminal;
a second terminal;
a transistor element including a source electrode, a drain electrode, and a gate electrode, the source electrode being electrically connected to the first terminal, the drain electrode being electrically connected to the second terminal;
a control circuit including a first control input portion, a second control input portion, a control output portion, and a control power supply input portion, the first control input portion being electrically connected to the first terminal, the second control input portion being electrically connected to the second terminal, the control output portion being electrically connected to the gate electrode;
a voltage generating circuit including a first voltage input portion, a second voltage input portion, and a voltage output portion, the first voltage input portion being electrically connected to the first terminal, the second voltage input portion being electrically connected to the second terminal, the voltage output portion being electrically connected to the control power supply input portion.

2. The diode device according to claim 1, wherein
the control circuit is configured to control a gate potential of the gate electrode based on a result of comparing a first potential of the first terminal with a second potential of the second terminal.

3. The diode device according to claim 2, wherein
the control circuit includes a comparison circuit,
the comparison circuit is configured to output a signal based on a difference between the first potential and the second potential.

4. The diode device according to claim 3, wherein
the comparison circuit includes a current mirror circuit and a differential circuit pair.

5. The diode device according to claim 4, wherein
the control circuit includes a buffer circuit,
the buffer circuit is provided between the comparison circuit and the control output portion.

6. The diode device according to claim 3, wherein
the comparison circuit includes one or more nMOS transistors.

7. The diode device according to claim 2, wherein
the control circuit includes a first transistor, a second transistor, a third transistor, and a fourth transistor,
a first end of the first transistor and a second end of the second transistor are electrically connected to the first terminal,
a first other end of the first transistor is electrically connected to a third end of the third transistor,
a second other end of the second transistor is electrically connected to a fourth end of the fourth transistor,
a third other end of the third transistor and the fourth other end of the fourth transistor are electrically connected to the control power supply input portion,
a first gate of the first transistor and a second gate of the second transistor are electrically connected to the second other end,
a third gate of the third transistor is electrically connected to the first terminal, and
a fourth gate of the fourth transistor is electrically connected to the second terminal.

8. The diode device according to claim 7, wherein
at least one of the first transistor, the second transistor, the third transistor, or the fourth transistor is an nMOS transistor.

9. The diode device according to claim 7, wherein
the control circuit further includes a fifth transistor and a sixth transistor,
a fifth end of the fifth transistor is electrically connected to the first terminal,
a fifth other end of the fifth transistor is electrically connected to the control output portion,
a sixth end of the sixth transistor is electrically connected to the control output portion,
a sixth other end of the sixth transistor is electrically connected to the control power supply input portion,
a fifth gate of the fifth transistor is electrically connected to the second other end, and
a sixth gate of the sixth transistor is electrically connected to the first other end.

10. The diode device according to claim 9, wherein
at least one of the fifth transistor or the sixth transistor is an nMOS transistor.

11. The diode device according to claim 3, wherein
the voltage generating circuit is configured to output a constant voltage based on a voltage between the first terminal and the second terminal.

12. The diode device according to claim 3, wherein
the voltage generating circuit includes a first voltage generating diode, a first voltage generating transistor, and a first capacitor,
a first voltage generating anode of the first voltage generating diode is electrically connected to the second terminal,
a first voltage generating cathode of the first voltage generating diode is electrically connected to a first voltage generating drain of the first voltage generating transistor,
a first voltage generating source of the first voltage generating transistor is electrically connected to a first capacitor end of the first capacitor and the voltage output portion,
a first capacitor other end of the first capacitor and a first voltage generating gate of the first voltage generating transistor are electrically connected to the first terminal, and
the first voltage generating transistor is a depletion mode MOS transistor.

13. The diode device according to claim 12, wherein
the voltage generating circuit further includes a second voltage generating diode,
a second voltage generating anode of the second voltage generating diode is electrically connected to the first terminal, and
a second voltage generating cathode of the second voltage generating diode is electrically connected to the voltage output portion.

14. The diode device according to claim 13, wherein
the second voltage generating diode is a Zener diode.

15. The diode device according to claim 3, wherein
the transistor element includes a Schottky barrier transistor.

16. The diode device according to claim 3, wherein
the transistor element further includes a semiconductor member, a metal member, and a first insulating member,
the semiconductor member is located between the drain electrode and the source electrode in a first direction from the drain electrode to the source electrode,
the source electrode includes a first electrode portion and a second electrode portion,
the semiconductor member includes a first semiconductor region of a first conductivity type,
the first semiconductor region includes a first partial region, a second partial region, and a third partial region,
the gate electrode is located between the drain electrode and the first electrode portion in the first direction,
a direction from the second partial region to the second electrode portion is along the first direction,
the third partial region is located between the gate electrode and the second electrode portion in a second direction crossing the first direction,
the metal member includes a first metal portion,
the first metal portion is located between the gate electrode and the second electrode portion in the second direction,
the first metal portion forms a Schottky contact with the third partial region,
at least a part of the first insulating member is located between the gate electrode and the semiconductor member.

17. The diode device according to claim 16, wherein
the first metal portion includes at least one selected from the group consisting of Ti, W, Mo, Ta, Zr, Al, Sn, V, Re, Os, Ir, Pt, Pd, Rh, Ru, Nb, Sr, and Hf.

18. The diode device according to claim 16, wherein
the metal member further includes a second metal portion,
the second metal portion is located between the first partial region and the second electrode portion in the first direction,
a direction from at least a part of the gate electrode to the second metal portion is along the second direction, and
a second work function of the second metal portion is lower than a first work function of the first metal portion.

19. The diode device according to claim 16, wherein
the semiconductor member further includes a second semiconductor region of the first conductivity type,
the second semiconductor region is located between the first semiconductor region and the source electrode,
a second impurity concentration of the first conductivity type in the second semiconductor region is higher than a first impurity concentration of the first conductivity type in the first semiconductor region.

20. The diode device according to claim 1, further comprising:
a base including a base face,
a third direction from the base face to the transistor element crossing the base face, and
a direction from the base face to the control circuit being along the third direction.
